(19) United States
(12) Patent Application Publication
(10) Pub. No.: US 2025/0089572 A1
(43) Pub. Date: Mar. 13, 2025

(54) HYBRID ELECTROMECHANICAL TRANSFORMER

(71) Applicant: University of Florida Research Foundation, Inc., Gainesville, FL (US)

(72) Inventors: David P. Arnold, Gainesville, FL (US); Mdabdulhalim Miah, Gainesville, FL (US); Adrian Abdala Rendon Hernandez, Gainesville, FL (US); Spencer E. Smith, Gainesville, FL (US)

(21) Appl. No.: 18/580,480

(22) PCT Filed: Jul. 20, 2022
(86) PCT No.: PCT/US2022/073938

§ 371 Date: Jan. 18, 2024

Related U.S. Application Data
(60) Provisional application No. 63/223,756, filed on Jul. 20, 2021.

(51) Int. Cl. H10N 30/30; H01F 7/10; H01F 7/16; H02K 35/02

(52) U.S. Cl. CPC H10N 30/306; H01F 7/10; H01F 7/1615; H02K 35/02

(57) ABSTRACT

Various embodiments relate to a hybrid electromechanical transformer system and related methods. One such system comprises an electromechanical transformer device comprising an oscillating suspension element, wherein the oscillating suspension element comprises a platform and one or more suspension arms. The one or more suspension arms are attached to a respective side of the platform, wherein the oscillating suspension element further comprises a frame. The device further comprises at least one piezoelectric element attached to the one or more suspension arms of the oscillating suspension element of the oscillating suspension element: a piezoelectric transducer port coupled to the at least one piezoelectric element: a permanent magnet attached to the platform of the oscillating suspension element; a coil electrodynamically coupled with the permanent magnet and attached to the frame of the oscillating suspension element; and an electrodynamic transducer port coupled to the coil.

### CROSS-REFERENCE TO RELATED APPLICATION

This application claims priority to co-pending U.S. provisional application entitled, “Hybrid Electromechanical Transformer,” having Ser. No. 63/223,756, filed Jul. 20, 2021, which is entirely incorporated herein by reference.

### STATEMENT REGARDING FEDERALLY SPONSORED RESEARCH OR DEVELOPMENT

This invention was made with government support under Grant No. 1941529, awarded by the National Science Foundation. The government has certain rights in the invention.

### TECHNICAL FIELD

The present disclosure is generally related to wireless power transmission.

### BACKGROUND

As electronic devices become smaller and more portable, wireless power transmission (WPT) has become increasingly popular for device recharging. A growing sub-field in WPT is electrodynamic wireless power transmission (EWPT), which involves a mechanically resonating permanent magnet within a receiver. The mechanical energy of the resonating magnet is converted into electricity using one or more electromechanical transduction schemes (e.g. electromagnetic, piezoelectric, or capacitive). Compared to other WPT schemes, EWPT leverages low-frequency magnetic fields (<1 kHz), which safely pass through conductive media and have higher human field exposure limits (˜2 mTᵣₘₛ at 1 KHz).

Within an EWPT receiver, the most commonly explored electromechanical transduction schemes are electrodynamic (ED) and piezoelectric (PE). ED (sometimes called ‘electromagnetic’) schemes use the motion of the resonating magnet to generate an induced voltage in a receiver coil. Alternatively, PE methods use the resonating magnet to generate stress and consequently voltage in piezoelectric materials integrated within the receiver system.

Electromechanical devices using either piezoelectric or electrodynamic transduction have been proposed as an alternative to conventional magnetic transformers. These devices make use of a mechanical vibration or motion for passive transformation of voltage, current, or impedance. In order to maximize end-to-end power transfer efficiency, these devices often rely on the resonance of a high mechanical quality factor resonator, such that mechanical energy losses are minimized.

The notion of a piezoelectric transformer (PT) using a single piezoelectric body was first presented in a patent application by C. A. Rosen et al. in 1954 (that issued as U.S. Pat. No. 2,830,274). PTs convert electrical energy from one circuit into electrical energy in another circuit by using acoustic energy (in the form of mechanical vibrations) from certain piezoelectric materials driven at resonance. PTs are widely used in applications requiring small size, high step-up voltages, and good electromagnetic compatibility (EMC). One of the major advantages of PTs is their large quality factor, which may lead to a high electrical efficiency. Suzuki et al. reported on a PT for applications in power electronics and concluded that, at the driving frequency (≈19.4 kHz), the maximum electrical efficiency was 99.2% and a maximum output power of 100 W was obtained. Despite this feature, PTs are rarely used in low-frequency (<1 kHz) applications. One reason for this is that each PT topology has an optimum vibration mode—typically in the range of 10 KHz to 1 MHz—that will allow optimum energy transfer through the device. PTs have also been considered for step-down applications such as current adapters for battery chargers and switch-mode power supplies of electronic devices. Unfortunately, Rosen-type PTs exhibit high internal electrical impedance, which may exclude them from low-voltage/high-current applications. In those applications, designing PTs to meet the requirement of step-down power conversion implies the use of different vibration modes such as thickness-extensional and radial modes. There has been significant additional interest recently in using PTs for ultra-low-power wake up circuits whose applications extend to various domains such as healthcare, smart cities, industrial monitoring, agriculture and security surveillance. Bassirian et al. presented two MEMS-based piezoelectric resonators integrated in a wake up receiver with 7 nW of power consumption (in “Nanowatt-Level Wakeup Receiver Front Ends Using MEMS Resonators for Impedance Transformation,” IEEE Trans. Microw. Theory Tech., vol. 67, no. 4, pp. 1615-1627, April 2019). Yadav et al. reported on a wake-up receiver that uses piezoelectric transduction and dissipates only 4.4 μW (in “A 4.4-μW Wake-Up Receiver Using Ultrasound Data,” IEEE J. Solid-State Circuits, vol. 48, no. 3, pp. 649-660, March 2013). Few studies have been published on the potential of PTs as key elements for ultra-low voltage start-up circuits for energy harvesting applications. Camarda et al. proposed a MEMS-based PT that achieves a maximum voltage gain of 58 mV/V at 36.3 kHz (in “A 32 mV/69 mV input Voltage Booster Based on a Piezoelectric Transformer for Energy Harvesting Applications,” Sens. Actuators Phys., vol. 232, pp. 341-352, August 2015). Martinez et al. presented a start-up converter that uses PT and achieves voltage gain of 23.2 at 55.8 kHz (in “A 15-mV Inductor-Less Start-up Converter Using a Piezoelectric Transformer for Energy Harvesting Applications,” IEEE Trans. Power Electron., vol. 33, no. 3, pp. 2241-2253, March 2018).

In contrast to PTs, the inventors previously demonstrated the feasibility of an electrodynamic transformer (ET) operating at a very low resonance frequency of only 22 Hz (in “Experimental Demonstration of an Electrodynamic Transformer,” IEEE Trans. Magn., vol. 47, no. 10, pp. 4433-4436, October 2011). Like a PT, an ET leverages the mechanical domain to exchange electrical power between input and output ports, but uses electrodynamic transduction (interaction between a permanent magnet and coil) on both ports, in contrast to a PT, which uses piezoelectric transduction. Electrodynamic transducers generally exhibit much lower electrical impedance (correspondingly lower voltages and larger currents) in comparison to piezoelectric transducers. Additionally, ET's have shown a relatively constant resonance frequency irrespective of the load conditions, which overcomes some of the frequency tuning challenges commonly found with PTs.

As is well known to the electromechanical transducers and energy-harvesting community, ED transducers generally produce lower voltage and higher currents, whereas PE transducers produce higher voltages and lower currents; or, equivalently, ED transducers have lower output impedance than PE transducers. For example, in the paper by M. A. Halim, S. E. Smith, J. M. Samman and D. P. Arnold, “A High-Performance Electrodynamic Microreceiver for Low-Frequency Wireless Power Transfer,” IEEE MEMS Conference, January 2020, pp. 590-593, for a magnetic field strength of ˜0.4 mTᵣₘₛ, the induced voltage for the reported ED EWPT receiver was relatively low (˜2.1 Vᵣₘₛ), but a few milliwatts of power (˜1.8 mW) were generated. Under similar conditions, a PE device generated much higher voltages (˜9.2 Vᵣₘₛ) but produced a lower average power (˜0.13 mW). Higher output voltages are generally desired to enable higher power efficiency in the power management electronics that are required to convert the AC power waveforms into stable DC waveforms for charging batteries or powering devices such as sensors or electronic circuits. Another difference between ED and PE transducers is the overall size (and thickness) of the receiver. Because of the need for multiturn coils, ED transducers tend to have a bulkier volume and thicker profile than PE transducers. For the previously reported designs, the ED transducer had a thickness of 4.7 mm, whereas the PE transducer was only 1.5 mm. For integration with other modern electronics, a low profile is a critical requirement.

### SUMMARY

In accordance with the purpose(s) of the disclosure, as embodied and broadly described herein, the disclosure in one aspect, relates to a hybrid electromechanical transformer system and related methods that passively transfer electrical power by coupling electrodynamic and piezoelectric transducers. Such a system comprises an electromechanical transformer device comprising an oscillating suspension element, wherein the oscillating suspension element comprises a platform and one or more suspension arms. The one or more suspension arms are attached to a respective side of the platform, wherein the oscillating suspension element further comprises a frame. The device further comprises at least one piezoelectric element attached to the one or more suspension arms of the oscillating suspension element of the oscillating suspension element; a piezoelectric transducer port coupled to the at least one piezoelectric element; a permanent magnet attached to the platform of the oscillating suspension element; a coil electrodynamically coupled with the permanent magnet and attached to the frame of the oscillating suspension element; and an electrodynamic transducer port coupled to the coil.

In one or more aspects, for such systems, the at least one piezoelectric element comprises two piezoelectric elements connected in series; the permanent magnet comprises a laterally-magnetized, square permanent magnet; the coil comprises a square shaped electromagnetic coil; the device achieves a mechanical quality factor of at least 25; the device achieves a mechanical quality factor of at least 50; the device achieves a mechanical quality factor of at least 100; the device achieves a mechanical quality factor of at least 250; the device achieves a resonance frequency that is 200 Hz or less; the device achieves a resonance frequency that is 2 kHz or less; the device achieves a resonance frequency that is 20 KHz or less; the device achieves an input/output voltage gain of at least 10; the device achieves an input/output voltage gain of at least 20; the device achieves an input/output voltage gain of at least 40; the device achieves an input/output voltage gain of at least 80; the oscillating suspension element comprises a non-magnetic material; dimensions of the oscillating suspension element, the permanent magnet, and the at least one piezoelectric element are configured to determine a frequency of operation of the electromechanical transformer device; and/or the oscillating suspension element is physically restricted to only oscillate in a torsional rotation mode.

In one or more aspects, for such systems, an input signal source is connected to the electrodynamic transducer port and an external load is connected to the piezoelectric transducer port, wherein the electromechanical transformer device comprises a step-up transformer, wherein the electromechanical transformer device is configured to induce an electromagnetic force on the permanent magnet when an input signal is applied to the coil such that electromagnetic force causes the permanent magnet to oscillate, causing a strain on the oscillating suspension element that is converted into electricity via a direct piezoelectric effect.

In one or more aspects, for such systems, an input signal source is connected to the piezoelectric transducer port and an external load is connected to the electrodynamic transducer port, wherein the electromechanical transformer device comprises a step-down transformer, wherein the electromechanical transformer device is configured to generate a mechanical strain when an input signal is applied to the at least one piezoelectric element that stimulates a motion on the permanent magnet and causes a flux change in the coil that induces an electromotive force in the coil.

Other systems, methods, features, and advantages of the present disclosure will be or become apparent to one with skill in the art upon examination of the following drawings and detailed description. It is intended that all such additional systems, methods, features, and advantages be included within this description and be within the scope of the present disclosure.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A shows a block diagram of an exemplary hybrid electromechanical transformer in accordance with various embodiments of the present disclosure.

FIG. 1B shows an architecture of the exemplary hybrid electromechanical transformer of FIG. 1A using electrodynamic and direct piezoelectric transduction on its electrodynamic (ED) and piezoelectric (PE) ports, respectively.

FIG. 2A shows a finite-element analysis (FEA) simulation results for the first three resonance mode shapes of a model of the structure of FIG. 1B (coil is not shown).

FIG. 2B shows the frequency response for the open circuit output voltage of the model of an exemplary hybrid step-up transformer.

FIG. 3 shows a block diagram and photograph of an experimental testbed for characterizing an exemplary hybrid electromechanical transformer in accordance with various embodiments of the present disclosure.

FIG. 4 shows a measured frequency response of an exemplary hybrid step-up transformer for its RMS (Root Mean Square) open-circuit output voltage and open-circuit voltage gain. The insets show the zoomed-in graph of RMS open-circuit output voltage at resonance.

FIG. 5 shows a plot of measured RMS voltage across and time-average power delivered to a variable load resistance when an exemplary hybrid step-up transformer is operated at 729.5 Hz (Mode 1) and 1015 Hz (Mode 3) resonance frequencies.

FIG. 6 shows a plot of measured power efficiency and power dissipation as a function of load resistance of an exemplary hybrid step-up transformer in accordance with various embodiments of the present disclosure.

FIG. 7 shows a plot of measured RMS voltage across and time-average power delivered to load resistance as a function of input voltage of an exemplary hybrid step-up when load resistances and resonance frequencies are 675 kΩ & 875 kΩ and 729.5 Hz (Mode 1) & 1015 Hz (Mode 3), respectively.

FIG. 8 shows a plot of measured power efficiency and power dissipation as a function of input voltage of an exemplary hybrid step-up transformer when load resistances and resonance frequencies are 675 kΩ & 875 kΩ and 729.5 Hz (Mode 1) & 1015 Hz (Mode 3), respectively.

FIG. 9 shows a plot of measured electrical impedance magnitude and phase angle of the piezoelectric (PE) port of an exemplary hybrid step-up transformer upon excitation of 500 mV being applied to the electrodynamic (ED) port.

FIG. 10 shows a plot of a measured frequency response of an exemplary hybrid step-down transformer for its RMS (Root Mean Square) open-circuit output voltage and open-circuit voltage gain. The insets show the zoomed-in graph of RMS open-circuit output voltage at resonance.

FIG. 11 shows a plot of measured RMS voltage across and time-average power delivered to a variable load resistance when an exemplary hybrid step-down transformer is operated at 728.5 Hz (Mode 1) and 1002 Hz (Mode 3) resonance frequency.

FIG. 12 shows a plot of measured efficiency and power dissipation as a function of load resistance of an exemplary hybrid step-down transformer in accordance with various embodiments of the present disclosure.

FIG. 13 shows a plot of measured RMS voltage across and time-average power delivered to a load resistance as a function of input voltage of an exemplary step-down hybrid transformer when load resistances and resonance frequencies are 230 Ω & 95 Ω and 728 Hz (Mode 1) & 1002 Hz (Mode 3), respectively.

FIG. 14 shows a plot of measured power efficiency and power dissipation of an exemplary step-down hybrid transformer as a function of input voltage when load resistances and resonance frequencies are 230 Ω & 95 Ω and 728 Hz (Mode 1) & 1002 Hz (Mode 3), respectively.

FIG. 15 shows a plot of measured electrical impedance magnitude and phase angle of the electrodynamical (ED) port of an exemplary hybrid step-down transformer upon excitation of 500 mV being applied to the piezoelectric (PE) port.

FIG. 16 shows a schematic of an AC-DC step-up converter for low-voltage signal using hybrid electromechanical transformer in accordance with embodiments of the present disclosure.

### DETAILED DESCRIPTION

The present disclosure describes various embodiments of systems and apparatuses and related methods of a hybrid electromechanical transformer that passively transfers electrical power by coupling electrodynamic and piezoelectric transducers. The use of these two complementary electromechanical transduction methods along with a high-Q mechanical resonator affords very large transformations of voltage, current, or impedance.

In one embodiment of the present disclosure, among others, a chip-size prototype is designed, simulated, fabricated and experimentally characterized. The 7.6 mm×7.6 mm×1.65 mm device achieves a voltage gain of 31.4 (29.9 dB) and 48.7 (33.7 dB) when operating as step-up transformer at 729.5 Hz and 1015 Hz resonance frequencies, respectively. When operating as a step-down transformer, the resonance frequencies and the corresponding voltage gains are 728 Hz, 1002 Hz, and 0.0097 (−40.2 dB), 0.0128 (−37.9 dB), respectively. A maximum power conversion efficiency of 11.8% is achieved, which is predominantly limited by the mechanical quality factor of the resonator.

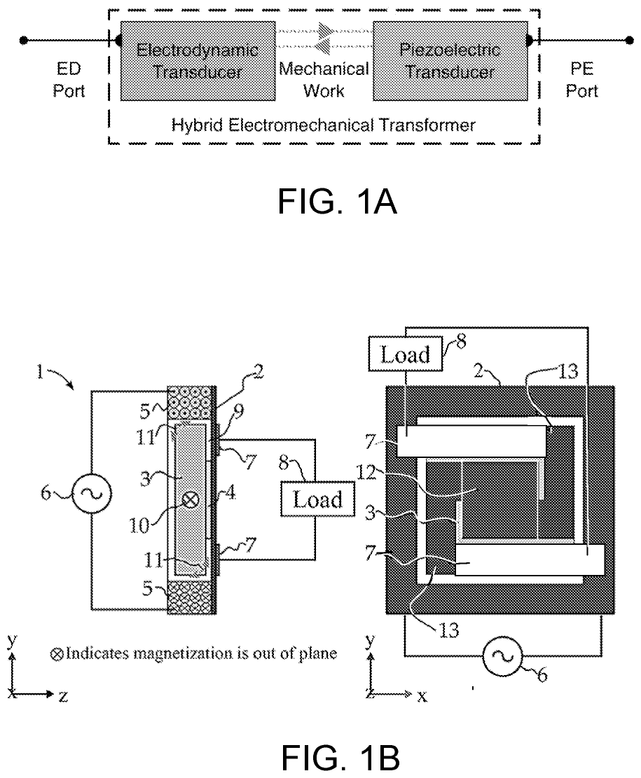

Accordingly, the present disclosure presents results on a multi-transduction device, termed a “hybrid electromechanical transformer,” that enables sub-1μW power dissipation, low driving frequency, high voltage gain, passive operation, bi-directional power conversion, low-profile and coreless design. An exemplary hybrid electromechanical transformer uses a coupling between magnetic, mechanical, and electrical domains to exchange electrical power between electrodynamic (ED) and piezoelectric (PE) ports, as illustrated in FIG. 1A. In general, an exemplary device comprises an oscillating suspension that connects electrodynamic and piezoelectric transducers. A laterally-magnetized, square permanent magnet attached to the suspension through a spacer and surrounded by and electrodynamically coupled with a square electromagnetic coil anchored to the suspension forms the electrodynamic transducer. The piezoelectric transducer comprises two piezoelectric unimorphs electrically connected in series, which are adhered to the clamped arms of the suspension (on the face opposite to the permanent magnet).

Correspondingly, FIG. 1B presents the architecture for the an exemplary hybrid electromechanical transformer. In particular, FIG. 1B illustrates the lateral (left side of figure) and aerial (right side of figure) views of the hybrid electromechanical transformer. Referring to FIG. 1B, the figure shows an electromechanical transformer 1 comprising an oscillating suspension body 2 of rectangular construction having a mounting central platform connected to meandered arms 13. The oscillating structure 2 is of non-magnetic material such as, but not limited to, titanium. The permanent magnet 3 is attached to the center platform 12 of body 2 via a spacer 4. The permanent magnet 3 is of Neodymium-Iron-Bore or any other type of rare-earth magnet, whose magnetization 10 is of laterally type (out of plane). The spacer is of a semiconductor material such as silicon or of a non-magnetic material such as titanium. There is an air-gap 9 between the permanent magnet 3 and the center platform 12 of the oscillating structure 2. A set of piezoelectric elements 7 transversely polarized and opposed with respect to one another are attached to the meandered arms 13 of the suspension. Electrodes or ports for the transformer 1 are the wires of the electromagnetic coil 5 and the upper surfaces of the piezoelectric elements 7, for the electrodynamic and piezoelectric transducers, respectively. The dimensions of the bodies 2, 3, 4, 7, 12, 13 and the number of turns in 5 along with positioning of the piezoelectric elements 7 are determinative respectively of the frequency of operation of the transformer and the transformation ratio of the transformer.

A source 6 of alternating current potentials is shown, having its terminals or ports connected to the electromagnetic coil 5. An electrical load device 8 is shown having connections to the electrodes of the piezo-elements 7. The wires coupling the load 8 and the electrodes 7 should be of similar construction to the wires by which the source 6 is coupled. On the oscillating body 2, the boundary conditions restrict it to oscillate in torsional rotation mode. In the present device, oscillation in the fundamental mode is illustrated 11, and the frequency at which this mode occurs may be predicted by finite element analysis. When an AC voltage source 6 is applied to the wires of the electromagnetic coil 5, a current flows in the coil and induces an electromagnetic force on the magnet 3. The force causes the magnet 3 to oscillate, causing a stress and strain on the oscillating structure 2 and consequently on the piezo-elements 7. The strain will take the form of an extension and contraction alternatively while the magnet 3 is oscillating in torsional rotation. This strain is then converted into electricity by means of direct piezoelectric effect. If the body 2 is chosen to resonate in the fundamental mode of torsional oscillation, then the magnet 3 and the body 2 will be excited to resonate with greatly intensified stresses and strains. Once the body 2 has been driven into a resonance condition of oscillation, effective transduction action occurs.

Accordingly, in the step-up transformer configuration, an AC voltage source is connected to the ED port, while an external load is connected to the PE port. When an electric current circulates in the electromagnetic coil, it induces electrodynamic force on the permanent magnet. The force provokes the magnet to oscillate, causing a mechanical stress on the suspension and similarly on the piezoelectric elements which is then converted into electricity by means of the direct piezoelectric effect. For the step-up configuration, the input current may be fixed in an attempt to minimize the input voltage, and thus the input power, at the electromagnetic coil.

Alternatively, the input signal source and external load may be connected to the PE and ED ports, respectively, to operate this device as a step-down transformer. In step-down transformer mode, when an AC voltage is applied to the PE port, a dynamic mechanical strain is generated by means of the converse piezoelectric effect, and this in turn will stimulate a motion on the magnet causing a flux change in the electromagnetic coil. This flux change induces an electromotive force (EMF) in the electromagnetic coil by means of Faraday's law of induction. For the step-down configuration, the input power may be fixed in order to minimize the input voltage across the piezoelectric elements.

In brief, the basic function of a transformer is transferring electric energy from one AC circuit to another circuit, either increasing or reducing the voltage. In conventional magnetic transformers, the voltage gain depends on the coil turns ratio. However, in a hybrid electromechanical transformer, the voltage gain depends on the magnetic field pattern produced by the magnet, the number of turns in the electromagnetic coil, and the size and shape of both the suspension and the piezoelectric elements. Naturally, this intensifies the design complexity of hybrid electromechanical transformers. Accordingly, the resonance behavior and frequency response of the system are studied by a 3D finite-element analysis (FEA) and then validated by experimental measurements.

To determine the open circuit voltage gain-the ratio of the RMS (Root Mean Square) output voltage to the RMS input voltage-of the hybrid electromechanical transformer, for its two power conversion types, the frequency of the input signal is varied over a certain range including the resonance torsional modes of the suspension. As the oscillating suspension approaches torsional resonance, its torsional amplitude reaches a maximum rotation, leading to peaks of power conversion. In both power conversion types (step-up and step-down transformer configurations), maximum voltage gain and power efficiency are expected to be achieved at the torsional resonance of the mechanical suspension and when the external load approaches the output port electrical impedance. Additionally, by connecting a variable load resistance to the output port, the optimum load resistance for maximum power transfer and corresponding power efficiency of each independent torsional transfer and corresponding power efficiency of each independent torsional resonance mode of the transformer can be determined for both power conversion modes.

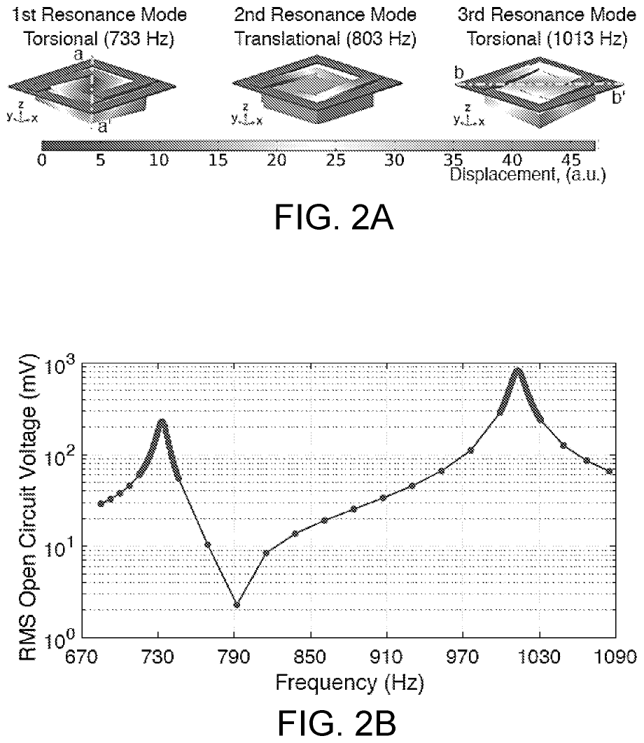

For system simulations, finite-element analysis was carried out using COMSOL Multiphysics®. First, a modal study was performed by a 3D model of the system. FIG. 2A shows the first three resonance mode shapes and natural frequencies of the system. To simulate the bonding layers (between the magnet, spacer and mounting platform, and between piezo-elements and suspension arms), a 20 μm-thick elastic layer with Young's modulus E=2 GPa and Poisson's ratio v=0.25 is used. It should be noted that the system exhibits two different torsional modes: first resonance mode shape occurs at 733 Hz, which is a torsional rotation about the diagonal axis a-a′, while the third mode of vibration at 1013 Hz is a torsional rotation about the diagonal axis b-b′. The second mode shape at 803 Hz corresponds to a displacement mode in the z-direction.

Second, a frequency domain study is carried out to investigate the frequency response of the hybrid electromechanical transformer for its open circuit output voltage when operated in a step-up transformer connection. For this simulation, an AC current signal of 100 μAᵣₘₛ is applied to the electromagnetic coil along with a damping ratio ζ=0.0064, corresponding to a Q-factor of 78.1 (as measured experimentally). As shown in FIG. 2B, the open circuit voltage, evaluated at the piezoelectric elements, reaches two positive peaks: the first one of 228.3 mVᵣₘₛ at 733 Hz and the second one of 823.4 mVᵣₘₛ at 1013 Hz. A negative peak of 2.3 mVᵣₘₛ is observed near 803 Hz where the system is expected to resonate in vertical displacement along the z-direction.

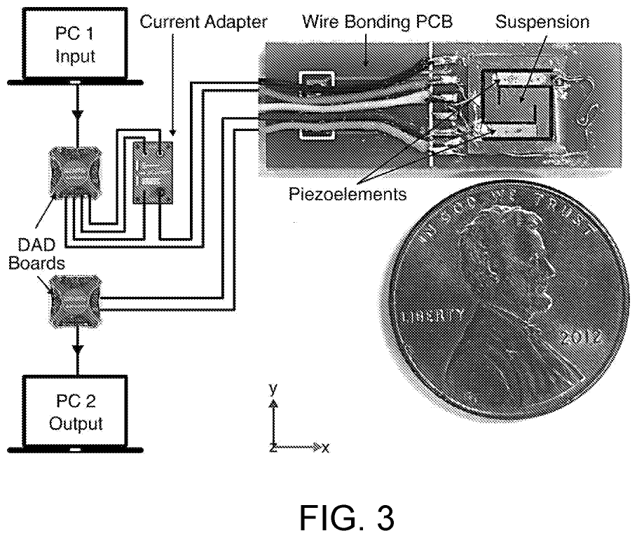

To demonstrate various concepts of the present disclosure, a hybrid electromechanical transformer prototype was fabricated and experimentally characterized. FIG. 3 shows the block diagram and photograph of an experimental testbed for testing the hybrid transformer. The suspension structure was fabricated by laser micro-machining 125 μm-thick titanium (Ti) shim stock (McMaster-Carr, IL, USA). The dimensions of the suspension are 7.6 mm×7.6 mm. The width of the suspension arms is 1 mm, and the center platform dimensions (where the magnet is attached via a spacer) are 2.6 mm×2.6 mm. The spacer, made of silicon (Si), was diced out of a 200 μm-thick, double side polished Si wafer (University Wafer, Inc., MA, USA). A laterally magnetized permanent magnet NdFeB grade N50 (Super Magnet Man, AL, USA) was bonded to one side of the center platform via a spacer using cyanoacrylate. On the opposite side, two piezo-ceramic patches, each 5 mm×1 mm×127 μm, diced from a PZT-5A4E sheet with sputtered nickel electrodes and poled through their thickness (Piezo.com, MA, USA), were bonded to the arms of the suspension using silver epoxy (EO-21M-5, EpoxySet Inc., RI, USA) to form a series connection between two unimorph piezoceramic transducers. A custom, commercially wound, rectangular, self-supported copper electromagnetic coil (44 AWG, 328 turns, 71 (DC resistance) whose inner dimensions are 5.6 mm×5.6 mm×1.4 mm, was glued using cyanoacrylate to the suspension so that it surrounds the permanent magnet. Finally, the assembled device was bonded using cyanoacrylate into a cutout on a printed circuit board (PCB). The PCB mechanically supports and electrically connects the hybrid electromechanical transformer and its ports, respectively. Electrical connections between PCB terminals and piezoelectric electrodes were made by attaching copper wires using silver epoxy. Soldered connections between these copper wires and corresponding PCB terminals, as well as between the coil wires and PCB, were used. From the block diagram of FIG. 3, we can see that a USB digital oscilloscope and a waveform generator (Diligent Analog Discovery 2, or “DAD”) were used to supply the input signal and to measure the output response, respectively. Note that a precision current adapter (μCurrent® Gold) was also used to measure the microamps level current circulating through the electromagnetic coil.

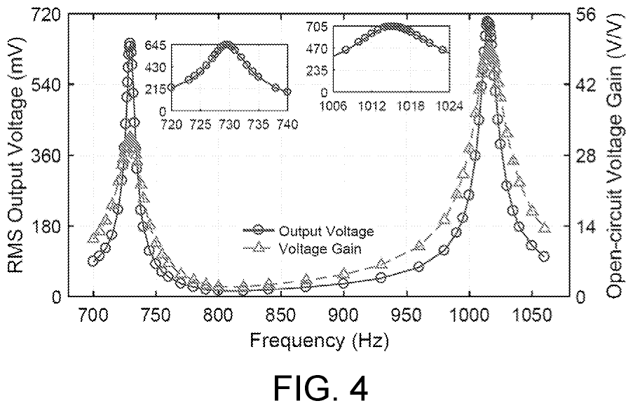

When operated as a step-up transformer the frequency response of the open circuit voltage gain was determined, as shown in FIG. 4. To do this, an AC voltage signal was generated by an arbitrary waveform generator (Diligent Analog Discovery 2) and was fed into the electromagnetic coil of the transformer's ED port. The voltage and current were measured using the USB digital oscilloscope built-in on the same data acquisition board. A second DAD board along with a high input impedance (10 MΩ) passive probe was used to measure the output voltage from the transformer's PE port, in which the sweep was carried out at a fixed input current (100 μAᵣₘₛ). From the insets of FIG. 4, the output voltage resonance peak indicates a Q-factor value of 112.2 (Mode 1) and 78.1 (Mode 3). Additionally, FIG. 4 shows that two peaks of open circuit voltage gain of 31.4 (29.9 dB) and 48.7 (33.7 dB) were achieved at 729.5 Hz and 1015 Hz, respectively. Additionally, a minimum voltage gain of 1.9 (5.5 dB) is observed close to 820 Hz, where the translational resonance of the suspension is expected to occur. The frequencies of the resonance modes closely match with those predicted by the 3D-FEA model (733 Hz, 803 Hz, and 1013 Hz).

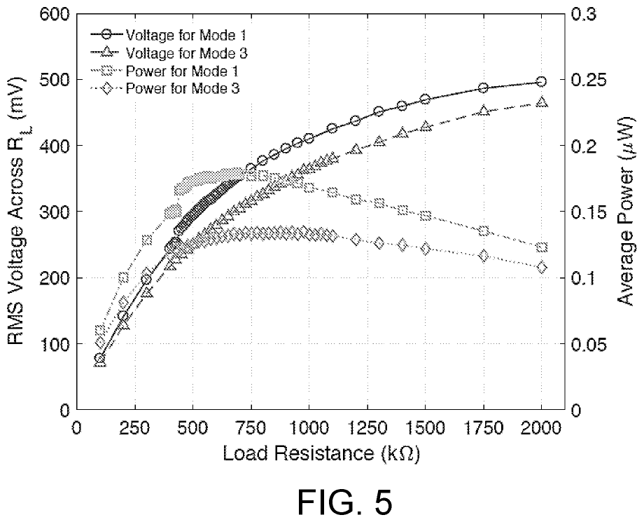

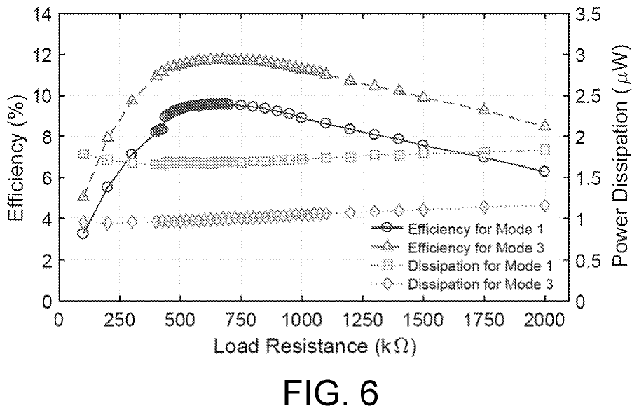

Next, FIG. 5 shows the RMS voltage and corresponding time-average power delivered to various load resistances (within the range of 100 kΩ to 2000 kΩ) while a 100 μAᵣₘₛ constant-amplitude alternating input current at frequencies of 729.5Hz (Mode 1) and 1015 Hz (Mode 3) was maintained. Making use of the measured effective voltage (Vᵣₘₛ), the time-average power was calculated by using Vᵣₘₛ/R_{L}, where R_{L} is the load resistance value. These experiments reveal that a maximum power of 0.18 μW and 0.13 μW are delivered to an optimum load resistance (for maximum power transfer) of 675 kΩ and 875 kΩ, respectively. Exploiting these findings, the power efficiency was estimated by using the ratio of the power delivered to R_{L} to the power supplied to the system, i.e., Pₒᵤₜ/Pᵢₙ. The input power was obtained by measuring the time-average product of the input current and voltage waveforms. FIG. 6 presents the measured efficiency and power dissipation of the transformer. As seen in FIG. 6, a maximum efficiency and associated power dissipation of 9.6% and 1.7 μW, respectively, are reached when a load resistance of 690 kΩ is used while operating in Mode 1 (729.5 Hz). As regards the operation in Mode 3 (1015 Hz), a maximum efficiency and power dissipation of 11.8% and 0.9 μW, respectively, are achieved when a load resistance of 625 kΩ is connected.

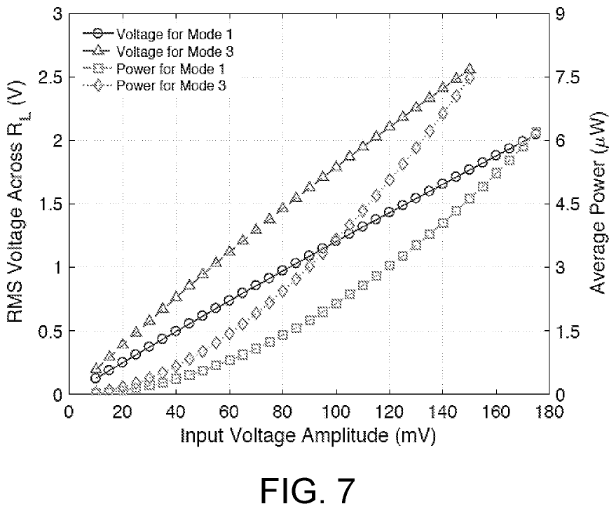

The voltage across and the time-average power delivered to the optimum load resistances were measured by varying the amplitude of an AC input voltage (within the range of 10 mV to 175 mV) with constant frequency of 729.5 Hz and 675 kΩ as the load resistance. This experiment was then replicated under conditions in which the input voltage ranged from 10 mV to 150 mV, at 1015 Hz resonance frequency and 875 kΩ load resistance, as shown in FIG. 7. As expected, the output time-average power shows a quadratic behavior as the input voltage increases.

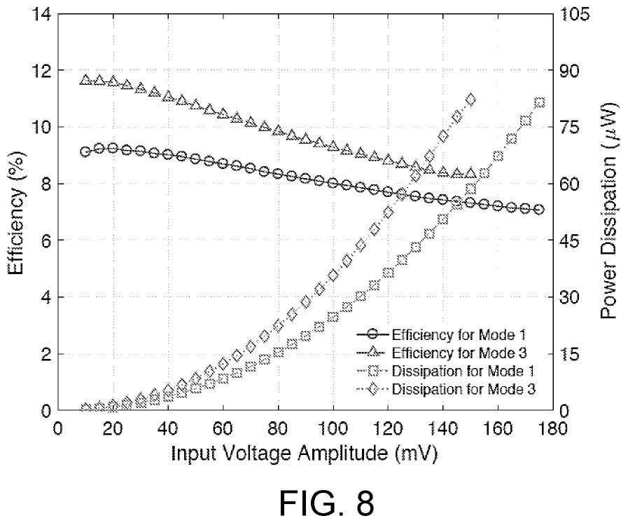

Moreover, the efficiency and power dissipation as a function of input voltage for each independent torsional resonance mode (while corresponding optimum load is connected) was calculated as reported in FIG. 8. Inventors believe that the power loss is primarily attributable to mechanical damping of the suspension and resistance of the electromagnetic coil. In the future, power efficiency can be improved by a material optimization for the mechanical resonator—with a very high-quality factor—and optimizing the dimensions and shape of the coil and magnetic circuit.

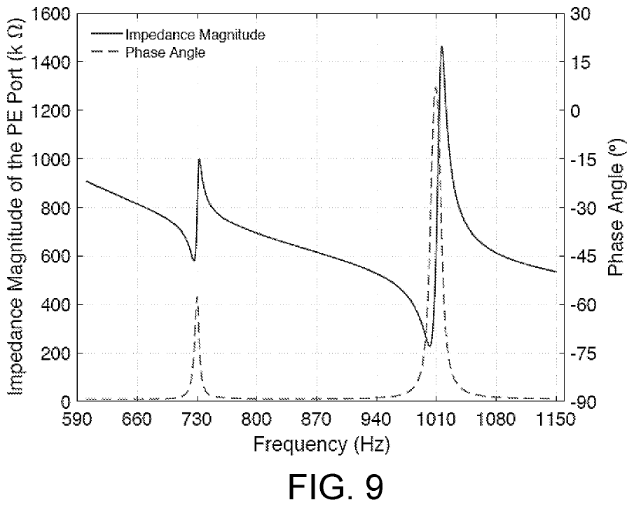

Knowledge of the electrical impedance of the two ports is important for end applications. Using a precision impedance analyzer (Hewlett Packard 4294A), the electrical impedance of the PE port of the hybrid electromechanical transformer was measured. FIG. 9 presents the electrical impedance magnitude and phase angle of the PE port. While two electrical impedance minimas of 580.1 kΩ at 726.5 Hz and 227.4 kΩ at 1002 Hz are associated with the torsional resonance frequencies of the PE transducer, two electrical impedance maximas of 998.7 kΩ at 732 Hz and 1.46 MΩ at 1015.9 Hz correspond to its torsional antiresonance frequencies. Substituting these results into k_{eff}=\sqrt{(fₐ²−fᵣ²)}/fₐ, where fᵣ and fₐ are the resonance and anti-resonance frequencies, respectively, the effective electromechanical coupling coefficient (k_{eff}) of the PE transducer was determined as 12.2% (Mode 1) and 16.4% (Mode 3).

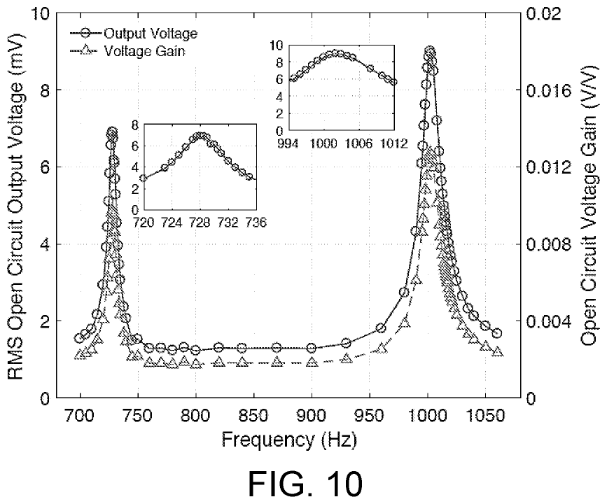

After the characterization of the step-up transformer type was complete, the device was then characterized as a step-down transformer. First, the frequency response of the hybrid electromechanical transformer was examined, as shown in FIG. 10. The PE port was used to feed the input voltage signal while the ED port read out the output signals. As stated above, the input power was kept constant (500 μW) to minimize the voltage across the piezoelectric elements. It is apparent from insets of FIG. 10 that the mechanical quality factor Q is 107.1 and 65.1 for Mode 1 and Mode 3, respectively. FIG. 10 shows two open-circuit voltage gain peaks of 0.0097 (−40.2 dB) and 0.0128 (−37.8 dB) at 728 Hz and 1002 Hz, respectively. A possible reason for this shift in resonance frequencies with respect to those reported for the step-up transformer type (729.5 Hz and 1015 Hz) may be in part because of the nonlinear resonance effect—resonance frequencies depend on the amplitude of oscillations.

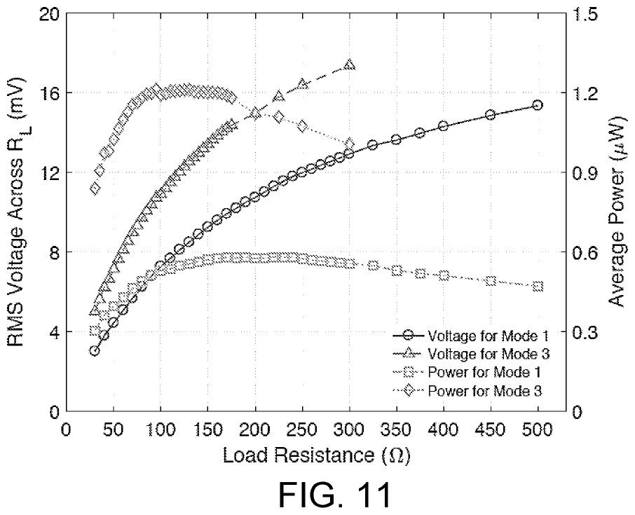

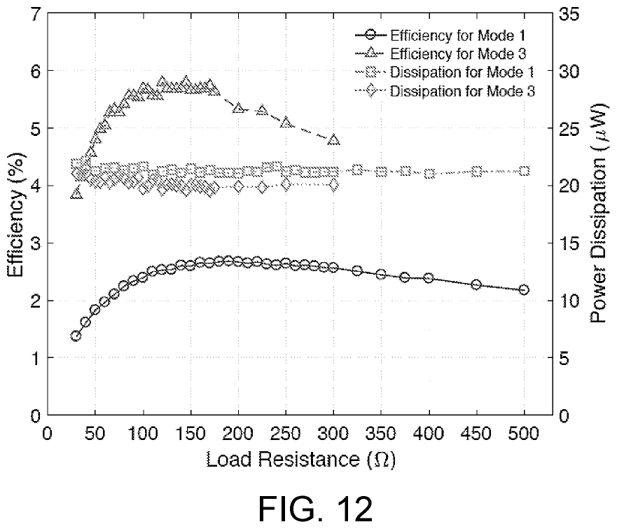

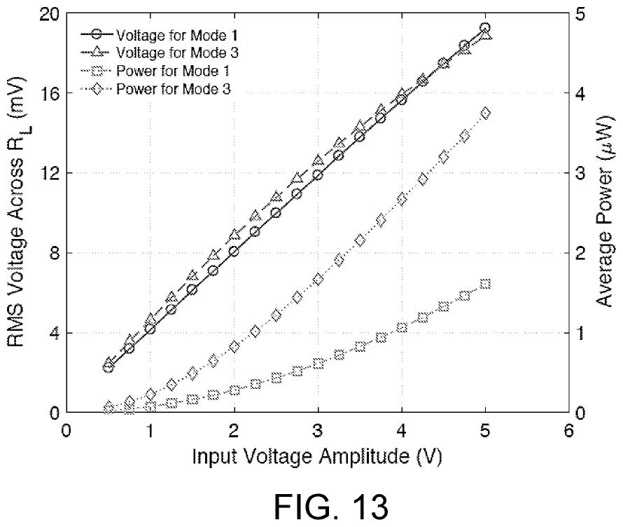

Next, the RMS voltage across and time-average power delivered to a variable load resistance were measured, as reported in FIG. 11. Results indicate that the power is maximized at 0.581 μW at 230 Ω at 1.213 μW at 95 Ω for Modes 1 and 3, respectively. Making use of this measured time-average power, the efficiency and power dissipation of the step-down transformer as a function of load resistance were estimated, as shown in FIG. 12. As seen in FIG. 12, efficiency peaks of 2.67% (Mode 1) and 5.79% (Mode 3) are reached when load resistances of 190 Ω and 120 Ω are used, respectively. The power dissipation associated with these peaks are 21.6 μW (Mode 1) and 20.7 μW (Mode 3). FIG. 13 presents the rms voltage across, and time-average power delivered to load resistance as a function of input voltage when the step-down transformer is operated at 728 Hz (Mode 1) and 1002 Hz (Mode 3). It is important to note that the optimum load resistance used was the one that will maximize the power transfer, specifically: 230 Ω and 95 Ω for Mode 1 and Mode 3, respectively. The amplitude of the input voltage was varied within the range of 0.5 V to 5 V. These results correlate satisfactorily with the quadratic behavior of the system's output power

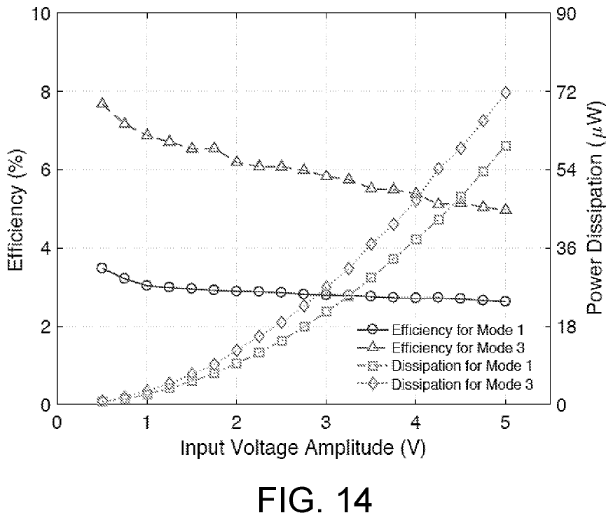

Further, the efficiency and power dissipation as a function of input voltage of the loaded (with corresponding optimum load resistance) step-down transformer are presented in FIG. 14. Material and topology optimization for the mechanical resonator (including piezoelements) and magnetic coil, respectively, would be needed to improve efficiency. Results reveal that the power efficiency also suffers a reduction with the increase of the input voltage. It is believed that power losses are due to mechanical and dielectric losses in the piezoelectric elements, as well as to mechanical damping of the oscillating suspension.

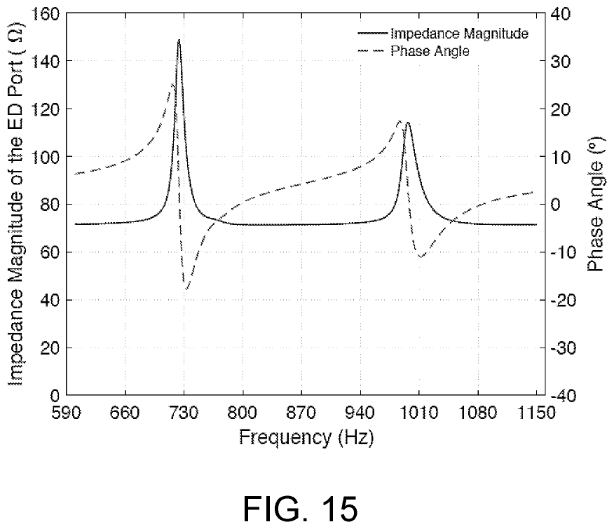

Finally, additional measurements of the electrical impedance of the ED port were performed using a precision impedance analyzer (Hewlett Packard 4294A). FIG. 15 shows the electrical impedance magnitude and phase angle of the ED port. It can be seen from these results that the electrical response of the ED port is dominated by a first peak impedance of 148.3 Ω at 724.4 Hz and a second peak of 113.4 Ω at 998 Hz for the resonance modes 1 and 3, respectively. Despite the fact that these peak impedances are slightly different from the optimum load resistances, a significant correlation between these values was found. As mentioned above in the Prototype preparation subsection, the DC resistance of the electromagnetic coil (71 Ω) supports these results. Regarding the phase angle, it has 0 degrees at the resonance frequencies and, as expected in an inductive circuit, the current lags behind the voltage, resulting in a positive phase angle.

An exemplary hybrid electromechanical transformer described in the present disclosure demonstrates the feasibility of combining both electrodynamic transduction and piezoelectric transduction by means of a mechanical resonator (using torsional vibration modes) to transfer electrical energy from one circuit to another. In accordance with the present disclosure, an exemplary hybrid electromechanical transformer is able to perform reversible power conversion (step-up and step-down transformer type) at a low frequency (<1 kHz), low dissipation (0.9 μW), and is feasible as an alternative, low-profile (1.65 mm), alternative to replace PTs, ETs, and conventional magnetic transformers in certain applications.

From experimental analysis, an exemplary hybrid electromechanical transformer device, when operating as step-up transformer type, demonstrated open circuit voltage gain of 31.4 (29.9 dB) and 48.7 (33.7 dB) at 729.5 Hz and 1015 Hz resonance frequencies, respectively. In addition, power transfer efficiencies peaks and associated dissipation of 9.6%, 1.7 μW (Mode 1) and 11.8%, 0.9 μW (Mode 3), respectively, are obtained when load resistances of 675 kΩ and 875 kΩ are connected to the output port of the step-up transformer. The effective electromechanical coupling coefficient of the hybrid transducer PE port reaches the maximum value of 12.2% and 16.4%, corresponding to its resonance modes 1 and 3, respectively. Operating as a step-up transformer, the hybrid electromechanical transformer device demonstrates a maximum power of 0.179 μW (with 675 kΩ load resistance), corresponding to a power density as high as 1.88 μW·cm⁻³. Regarding the step-down transformer operation, the hybrid electromechanical transformer device achieved 0.0097 (−40.2 dB) and 0.0128 (−37.8 dB) open circuit voltage gain at 728 Hz (Mode 1) and 1002 Hz (Mode 3) resonance frequencies, respectively. In various embodiments, the power efficiency can be significatively improved by optimized dimensions of piezoelectric elements and better design of mechanical suspension and magnetic circuit to reduce power losses.

Since the prototype hybrid electromechanical transformer has demonstrated expected functionality and the experimental characterization has shown promise for high voltage transformation, this section attempts to investigate the potential application of the hybrid transformer through a simple application: an AC-DC step-up converter for low-voltage signals. Experimental demonstration and results are presented.

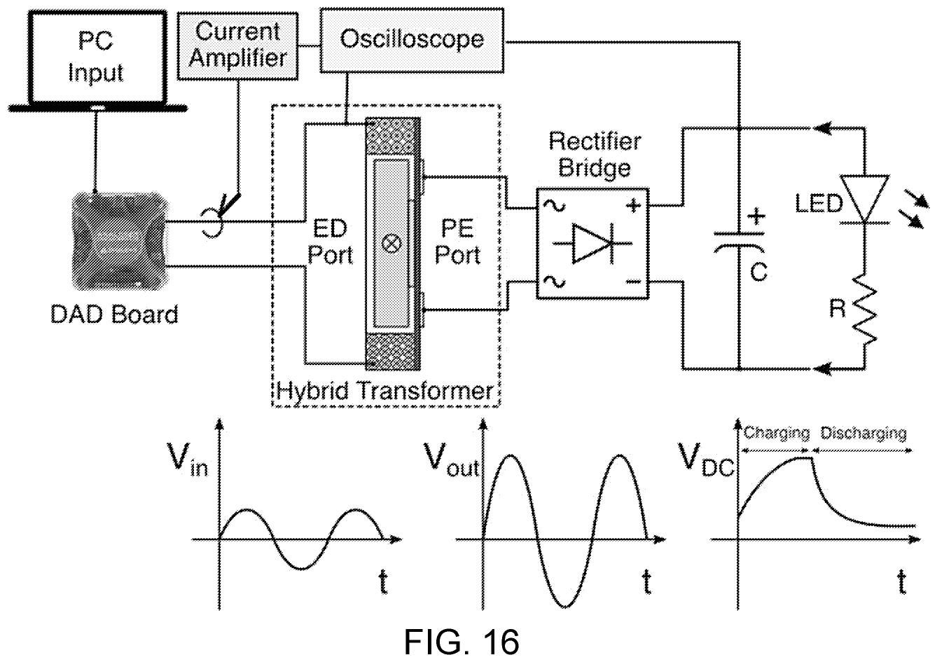

For this preliminary demonstration, some discrete electronic components, namely, 4 diodes, a capacitor, an LED, and a resistance were used to validate the concept. The system implementation is shown in FIG. 16. The demonstrated system is configured as an AC-DC step-up converter for low-voltage signals to power an LED. The input signal is provided by an arbitrary waveform generator DAD board, generating 500 mVₚₑₐₖ at a 1015 Hz (Mode 3) driving frequency. The power supply output is connected to the ED port of the hybrid electromechanical transformer. Note that the input current and voltage were measured by using a current clamp and a high input impedance (10 MΩ) passive probe, respectively, connected to an oscilloscope.

The stepped-up voltage (output voltage across the PE port of the transformer) is directly connected to a full wave rectifier bridge comprised by 4 diodes (1N4003). In order to smooth the pulsating DC output after rectification, a 470 μF electrolytic capacitor is connected to the output terminals of the rectifier bridge. As a result, the rectified voltage will be stored at the capacitor until an external load will drain this energy. Last, an external load formed by an LED and a 33 kΩ resistance (i.e., current limiter) connected in series, is connected in parallel with capacitor. The time constant of this circuit, τ=RC is 15.5 s. It can be seen during testing that the voltage of the capacitor decays exponentially during this discharge. The measured input voltage and current are 209 mVᵣₘₛ and 2.4 mAᵣₘₛ, while the DC output voltage reaches 5.3 V.

In general, the present disclosures describes an exemplary hybrid electromechanical transformer device that uses a coupling between magnetic, mechanical, and electrical domains to exchange electrical power between input and output ports. An exemplary transformer device comprises an oscillating structure including electrodynamic and piezoelectric transducers. The electrodynamic transducer can be constituted of a laterally magnetized permanent magnet attached to the oscillating structure by means of a spacer to create an air-gap, in which the magnet is electrodynamically coupled with an electromagnetic coil for the application of input potentials and is anchored to an outer frame of the oscillating structure. With regards to the piezoelectric transducer, it can be comprised of a body of piezo-electric material attached to the oscillating structure face, opposite to the magnet, and having electrodes applied to the body for the removal of the electric potentials developed in the body because of structure oscillations produced in turn upon application of input potentials.

Correspondingly, the operation of an exemplary hybrid electromechanical transformer may be described by a process involving an initial electrodynamic conversion of electrical energy into mechanical energy followed by a conversion of mechanical energy back to electrical energy. The mechanical energy is in the form of vibrational energy which corresponds to certain modes of vibration of the oscillating structure, namely torsional oscillation of the structure.

An exemplary hybrid electromechanical transformer has a very small footprint that can increase small voltages up to 20×-30× and can also operate in the 800 Hz range versus the 100 KHz range of typical electromechanical transformers which are large and bulky and can typically only increase voltage by 10×. A practical application of the hybrid electromechanical transformer is demonstrated through an AC-DC step-up converter for low-voltage signal. In one operational mode, (Mode 3, at 1015 Hz) and using an input signal whose voltage and current are only of 209 mVᵣₘₛ and 2.4 mAᵣₘₛ, respectively, the step-up converter achieves 5.3 VDC, which can be enough to turn on electronic devices such as low-voltage radio transmitters and start-up circuits for energy harvesting applications, to mention a few. Thus, exemplary embodiments of a hybrid electromechanical transformer device can be employed in various applications, such as, but not limited to, a wake up receiver, a power transformer, consumer electronics such as laptop screens, tablet screens, cell phones, etc. With appropriate design and circuitry, an exemplary embodiment of the hybrid electromechanical transformer may be employed in electrical circuits like backlighting inverters, driving the gate of MOSFET transistors while providing isolation, ozone generators for medical, sanitary and beauty related applications and air cleaners, etc.

In various embodiments, electromechanical transformer devices of the present disclosure can achieve mechanical quality factors of at least 25, 50, 100, and/or 250, among others. Correspondingly, in various embodiments, electromechanical transformer devices of the present disclosure can achieve a resonant frequency that is 200 Hz or less, 2 kHz or less, and/or 20 KHz or less, among others. Additionally, in various embodiments, electromechanical transformer devices of the present disclosure can achieve an input/output voltage gain of at least 10, 20, 40, and/or 80, among others.

It should be emphasized that the above-described embodiments are merely possible examples of implementations, merely set forth for a clear understanding of the principles of the present disclosure. Many variations and modifications may be made to the above-described embodiment(s) without departing substantially from the principles of the present disclosure. All such modifications and variations are intended to be included herein within the scope of this disclosure.

Therefore, at least the following is claimed:

1. An electromechanical transformer device comprising:
an oscillating suspension element, wherein the oscillating suspension element comprises a platform and one or more suspension arms, wherein the one or more suspension arms are attached to a respective side of the platform, wherein the oscillating suspension element further comprises a frame;
at least one piezoelectric element attached to the one or more suspension arms of the oscillating suspension element of the oscillating suspension element;
a piezoelectric transducer port coupled to the at least one piezoelectric element;
a permanent magnet attached to the platform of the oscillating suspension element;
a coil electrodynamically coupled with the permanent magnet and attached to the frame of the oscillating suspension element; and
an electrodynamic transducer port coupled to the coil.

2. The electromechanical transformer device of claim 1, wherein the at least one piezoelectric element comprises two piezoelectric elements connected in series.

3. The electromechanical transformer device of claim 1, wherein the permanent magnet comprises a laterally-magnetized, square permanent magnet.

4. The electromechanical transformer device of claim 1, wherein the coil comprises a square shaped electromagnetic coil.

5. The electromechanical transformer device of claim 1, wherein an input signal source is connected to the electrodynamic transducer port and an external load is connected to the piezoelectric transducer port, wherein the electromechanical transformer device comprises a step-up transformer, wherein the electromechanical transformer device is configured to induce an electromagnetic force on the permanent magnet when an input signal is applied to the coil such that electromagnetic force causes the permanent magnet to oscillate, causing a strain on the oscillating suspension element that is converted into electricity via a direct piezoelectric effect.

6. The electromechanical transformer device of claim 1, wherein an input signal source is connected to the piezoelectric transducer port and an external load is connected to the electrodynamic transducer port, wherein the electromechanical transformer device comprises a step-down transformer, wherein the electromechanical transformer device is configured to generate a mechanical strain when an input signal is applied to the at least one piezoelectric element that stimulates a motion on the permanent magnet and causes a flux change in the coil that induces an electromotive force in the coil.

7. The electromechanical transformer device of claim 1, wherein the device achieves a mechanical quality factor of at least 25.

8. The electromechanical transformer device of claim 7, wherein the device achieves a mechanical quality factor of at least 50.

9. The electromechanical transformer device of claim 8, wherein the device achieves a mechanical quality factor of at least 100.

10. The electromechanical transformer device of claim 9, wherein the device achieves a mechanical quality factor of at least 250.

11. The electromechanical transformer device of claim 1, wherein the device achieves a resonance frequency that is 200 Hz or less.

12. The electromechanical transformer device of claim 11, wherein the device achieves a resonance frequency that is 2 kHz or less.

13. The electromechanical transformer device of claim 12, wherein the device achieves a resonance frequency that is 20 KHz or less.

14. The electromechanical transformer device of claim 1, wherein the device achieves an input/output voltage gain of at least 10.

15. The electromechanical transformer device of claim 14, wherein the device achieves an input/output voltage gain of at least 20.

16. The electromechanical transformer device of claim 15, wherein the device achieves an input/output voltage gain of at least 40.

17. The electromechanical transformer device of claim 16, wherein the device achieves an input/output voltage gain of at least 80.

18. The electromechanical transformer device of claim 1, wherein the oscillating suspension element comprises a non-magnetic material.

19. The electromechanical transformer device of claim 1, wherein dimensions of the oscillating suspension element, the permanent magnet, and the at least one piezoelectric element are configured to determine a frequency of operation of the electromechanical transformer device.

20. The electromechanical transformer device of claim 1, wherein the oscillating suspension element is physically restricted to only oscillate in a torsional rotation mode.
